(19) United States
(12) Patent Application Publication
(10) Pub. No.: US 2026/0173788 A1
(43) Pub. Date: Jun. 18, 2026

(54) SUBSTRATE CLEANING APPARATUS AND SUBSTRATE CLEANING METHOD

(71) Applicant: EBARA CORPORATION, Tokyo (JP)

(72) Inventor: Hiroki TAKAHASHI, Tokyo (JP)

(21) Appl. No.: 19/412,533

(22) Filed: Dec. 8, 2025

(30) Foreign Application Priority Data
Dec. 12, 2024 (JP) 2024-217478

(51) Int. Cl. H10P 72/00; B08B 3/02; B08B 3/04; B08B 3/08; B08B 13/00; C11D 3/43

(52) U.S. Cl. CPC H10P 72/0414; B08B 3/022; B08B 3/024; B08B 3/041; B08B 3/08; B08B 13/00; C11D 3/43; B08B 2203/02

(57) ABSTRACT

A substrate cleaning apparatus (18) starts supply of a first rinse liquid to a surface (W1) of a substrate (W) from a rinse liquid nozzle (75). After formation of a liquid film for particle detachment on the surface (W1) of the substrate (W) with the first rinse liquid, dispensing of a jet flow of the cleaning liquid to the surface (W1) of the substrate (W) from the jet flow nozzle (72) is started, and movement of the cleaning arm (73) is started. Furthermore, after the movement of the cleaning arm (73) is started, supply of the second rinse liquid to the surface (W1) of the substrate (W) from the rinse liquid nozzle (75) is started, forming a liquid film for particle discharge on the surface (W1) of the substrate (W) with the second rinse liquid.

### BACKGROUND OF THE INVENTION

### Field of the Invention

The present invention relates to a substrate cleaning apparatus for cleaning the surfaces of a substrate.

### Description of the Related Art

In production of a semiconductor device, a CMP apparatus that planarizes the surface of a substrate conducts a polishing process to polish the surfaces of a substrate with polishing liquid (slurry) that contains abrasive grains and polishing aids, a cleaning process to remove the slurry adhering to the front and back surfaces of the substrate with cleaning liquid, and a drying process to remove droplets adhering to the front and back surfaces of the substrate due to the cleaning process. If the cleaning process is not appropriate, defects will occur in the structure of the device and they lead to faulty characteristics of the device. Thus, it is necessary to select a method for the cleaning process that reliably removes slurry within a short amount of time and without causing breakage or corrosion of the device.

Accordingly, some conventional substrate cleaning apparatuses apply scrub cleaning using a sponge member in the shape of a roll or a pencil, with various kinds of cleaning liquid supplied in the course of scrub cleaning. Some conventional substrate cleaning apparatuses also use two-fluid jet cleaning, which sprays a two-fluid jet flow consisting of mixed fluid of gas and liquid toward the substrate surface to clean it, as a form used in combination with the scrub cleaning mentioned above (see Japanese Patent No. 5866227, for example).

Two-fluid jet cleaning supplies a two-fluid jet flow from a two-fluid nozzle to the surface of the substrate while moving the two-fluid nozzle in parallel with the surface of the substrate, and detaches particles present on the substrate surface such as abrasive grains and polishing dust with a high-speed liquid flow that is created by collision between the two-fluid jet flow and the substrate. In two-fluid jet cleaning, by increasing the flow rate (flow velocity) of gas, micro droplets are produced from liquid and the spraying speed of droplets is enhanced. This can make a liquid flow that occurs on the substrate stronger.

With conventional substrate cleaning apparatuses, particles with a size of 100 nm or smaller are difficult to detach from the outermost surface of the substrate only with the physical action of a liquid flow. To address it, it is conceivable to assist in detachment of particles with chemical action by using cleaning liquid with an alkaline component or a surfactant component added.

However, the surface of a substrate immediately after polishing or immediately after scrub cleaning is covered with a liquid film of residual slurry or rinse water. The thicker the liquid film is, the longer the time required for liquid present near particle surfaces to be replaced with the alkaline component or the surfactant component. That is, as it is diffusion-controlled, chemical action on particles is weak and sufficient cleaning effect is not obtained.

However, if the above-mentioned liquid film is removed first in order to promote the chemical action on particles, particles completely cling to the outermost surface of a substrate W to become very difficult to detach. In addition, since sufficient liquid film is not present, detached particles are diffused by the flow of the liquid film, which makes them difficult to be discharged outside of the system. Consequently, they re-adhere to the outermost surface of the substrate W; and sufficient cleaning effect is not achieved.

The present invention has been made against the background outlined above. An object of the present invention is to provide a substrate cleaning apparatus that can achieve high cleaning effect.

### SUMMARY OF INVENTION

An aspect of the present invention is a substrate cleaning apparatus. The substrate cleaning apparatus includes: a substrate holding and rotating mechanism which holds a substrate and rotates the substrate at a predefined rotation number;
a cleaning arm disposed above the substrate;
a cleaning arm movement mechanism which moves the cleaning arm over the substrate in a predefined direction of movement;
a jet flow nozzle which is provided on the cleaning arm and dispenses a jet flow of cleaning liquid to a surface of the substrate;
a rinse liquid nozzle which is disposed above the substrate and dispenses a first rinse liquid supplied from a first rinse liquid source or a second rinse liquid supplied from a second rinse liquid source to the surface of the substrate; and
a control unit, the control unit performing substrate cleaning control including: starting supply of the first rinse liquid to the surface of the substrate from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid.

Another aspect of the present invention is a substrate cleaning method that is performed in a substrate cleaning apparatus. The substrate cleaning apparatus includes: a substrate holding and rotating mechanism which holds a substrate and rotates the substrate at a predefined rotation number; a cleaning arm disposed above the substrate; a cleaning arm movement mechanism which moves the cleaning arm over the substrate in a predefined direction of movement; a jet flow nozzle which is provided on the cleaning arm and dispenses a jet flow of cleaning liquid to a surface of the substrate; and a rinse liquid nozzle which is disposed above the substrate and dispenses a first rinse liquid supplied from a first rinse liquid source or a second rinse liquid supplied from a second rinse liquid source to the surface of the substrate. The substrate cleaning method includes: starting supply of the first rinse liquid to the surface of the substrate from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid.

As will be described below, the present invention has other aspects. Hence, the disclosure of this invention is intended to provide some of the aspects of the present invention and is not intended to limit the scope of the invention described and claimed herein.

### BRIEF DESCRIPTION OF THE DRAWINGS

FIG. 1 shows an example of a substrate processing apparatus;

FIG. 2 shows an example of the substrate cleaning apparatus (a second cleaning module) in an embodiment of the present invention;

FIG. 3 is a cross-sectional view showing an example of a two-fluid nozzle;

FIG. 4 is a schematic diagram illustrating a configuration of the substrate cleaning apparatus in an embodiment of the present invention;

FIG. 5 is a flow diagram for illustrating operation of the substrate cleaning apparatus in an embodiment of the present invention;

FIG. 6 is a schematic diagram illustrating the operation of the substrate cleaning apparatus in an embodiment of the present invention; and

FIG. 7 is a schematic diagram illustrating the operation of the substrate cleaning apparatus in an embodiment of the present invention.

### DETAILED DESCRIPTION OF THE INVENTION

The present invention is described in more detail below. However, the following detailed description and the attached drawings are not intended to limit the invention.

A substrate cleaning apparatus according to the present invention includes: a substrate holding and rotating mechanism which holds a substrate and rotates the substrate at a predefined rotation number; a cleaning arm disposed above the substrate; a cleaning arm movement mechanism which moves the cleaning arm over the substrate in a predefined direction of movement; a jet flow nozzle which is provided on the cleaning arm and dispenses a jet flow of cleaning liquid to a surface of the substrate; a rinse liquid nozzle which is disposed above the substrate and dispenses a first rinse liquid supplied from a first rinse liquid source or a second rinse liquid supplied from a second rinse liquid source to the surface of the substrate; and a control unit, the control unit performing substrate cleaning control including: starting supply of the first rinse liquid to the surface of the substrate from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid.

With this arrangement, the first rinse liquid is first supplied from the rinse liquid nozzle to the surface of the substrate. After formation of a liquid film for particle detachment on the surface of the substrate with the first rinse liquid, dispensing of a jet flow of the cleaning liquid to the surface of the substrate is started from the jet flow nozzle and movement of the cleaning arm is started. By doing so, a cleaning process with the cleaning liquid is performed with no particles clinging to the surface of the substrate, providing high cleaning effect. Furthermore, after the movement of the cleaning arm is started, the second rinse liquid is supplied to the surface of the substrate from the rinse liquid nozzle and a liquid film for particle discharge is formed on the surface of the substrate with the second rinse liquid. As a result, detached particles are diffused by a liquid flow to be discharged outside of the system, and inhibited from re-adhering to the surface of the substrate, providing high cleaning effect.

In the substrate cleaning apparatus of the present invention, the first rinse liquid may be liquid with smaller surface tension than that of pure water.

With this arrangement, the thickness of the liquid film for particle detachment formed on the surface of the substrate with the first rinse liquid can be easily controlled to be thin. When liquid film is not present on the surface of the substrate, particles cling to the surface of the substrate and become difficult to detach. On the other hand, when the liquid film on the surface of the substrate is too thick, cleaning liquid is less likely to reach the surface of the substrate, lowering the cleaning effect. According to the present invention, liquid film (thin liquid film) for particle detachment can be formed on the surface of the substrate, providing high cleaning effect.

In the substrate cleaning apparatus of the present invention, the first rinse liquid may be liquid containing an organic solvent component.

With this arrangement, the effect of removing organic matter from the surface of the substrate is provided by the first rinse liquid containing an organic solvent component.

In the substrate cleaning apparatus of the present invention, the cleaning liquid may be liquid containing at least one component of an alkaline component or a surfactant component.

With this arrangement, particles on the surface of the substrate can be detached not only by physical action of a liquid flow but also by chemical action (e.g., the effect of making the zeta potential assume a negative charge), providing high cleaning effect.

In the substrate cleaning apparatus of the present invention, the second rinse liquid may be the same liquid as the cleaning liquid or the first rinse liquid.

With this arrangement, use of the same liquid as the cleaning liquid for the second rinse liquid can provide the effect of suppressing re-adhesion of particles with chemical action (e.g., the effect of making the zeta potential assume a negative charge). In addition, if the first rinse liquid is an organic solvent, use of the same liquid as the first rinse liquid for the second rinse liquid can provide the effect of removing organic matter from the surface of the substrate.

In the substrate cleaning apparatus of the present invention, the jet flow nozzle may be a two-fluid nozzle that sprays a two-fluid jet flow of the cleaning liquid and gas to the surface of the substrate.

With this arrangement, the first rinse liquid is first supplied from the rinse liquid nozzle to the surface of the substrate, and after formation of a liquid film for particle detachment on the surface of the substrate with the first rinse liquid, spraying of a two-fluid jet flow to the surface of the substrate is started from the two-fluid nozzle and movement of the cleaning arm is started. By doing so, two-fluid cleaning is performed with no particles clinging to the surface of the substrate, providing high cleaning effect. For example, sufficient cleaning effect is obtained even for particles with a size of 100 nm or smaller.

A substrate cleaning method of the present invention is a substrate cleaning method that is performed in a substrate cleaning apparatus, the substrate cleaning apparatus including: a substrate holding and rotating mechanism which holds a substrate and rotates the substrate at a predefined rotation number; a cleaning arm disposed above the substrate; a cleaning arm movement mechanism which moves the cleaning arm over the substrate in a predefined direction of movement; a jet flow nozzle which is provided on the cleaning arm and dispenses a jet flow of cleaning liquid to a surface of the substrate; and a rinse liquid nozzle which is disposed above the substrate and dispenses a first rinse liquid supplied from a first rinse liquid source or a second rinse liquid supplied from a second rinse liquid source to the surface of the substrate, and the substrate cleaning method including: starting supply of the first rinse liquid to the surface of the substrate from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid.

According to this method, as with the foregoing apparatus, the first rinse liquid is first supplied from the rinse liquid nozzle to the surface of the substrate, and after formation of a liquid film for particle detachment on the surface of the substrate with the first rinse liquid, dispensing of a jet flow of the cleaning liquid to the surface of the substrate is started from the jet flow nozzle and movement of the cleaning arm is started. By doing so, a cleaning process with the cleaning liquid is performed with no particles clinging to the surface of the substrate, providing high cleaning effect. Furthermore, after the movement of the cleaning arm is started, the second rinse liquid is supplied to the surface of the substrate from the rinse liquid nozzle and a liquid film for particle discharge is formed on the surface of the substrate with the second rinse liquid. As a result, detached particles are diffused by a liquid flow to be discharged outside of the system, and inhibited from re-adhering to the surface of the substrate, providing high cleaning effect.

According to the present invention, high cleaning effect is achieved when the surfaces of a substrate are cleaned with the substrate cleaning apparatus.

### Embodiments

A substrate cleaning apparatus in an embodiment of the present invention is described below with the drawings. This embodiment describes a substrate cleaning apparatus that is used as a cleaning apparatus equipped with a two-fluid jet cleaning nozzle which sprays micro droplets with carrier gas at high speed, by way of illustration.

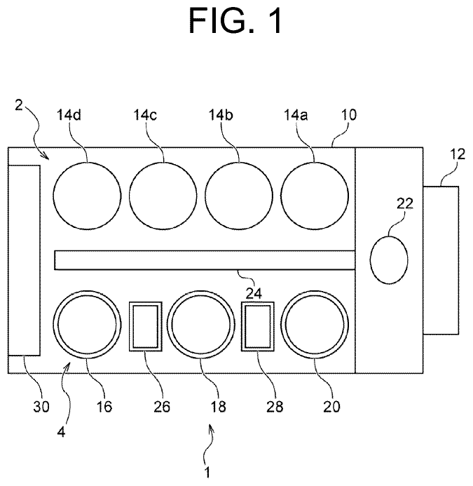

The configuration of the substrate cleaning apparatus in the embodiment of the present invention will be described with reference to the drawings. FIG. 1 shows an overall configuration of a substrate processing apparatus to which the substrate cleaning apparatus of this embodiment is applied. As shown in FIG. 1, a substrate processing apparatus 1 includes a housing 10, and a load port 12 on which a substrate cassette for stoking multiple substrates such as semiconductor wafers is placed. The load port 12 is disposed adjacent to the housing 10.

The substrate processing apparatus 1 includes a polishing section 2 and a cleaning section 4, which are disposed inside the housing 10. The polishing section 2 has multiple (four in this embodiment) polishing modules 14a to 14d. The cleaning section 4 includes a first cleaning module 16 and a second cleaning module 18 for cleaning a polished substrate, and a drying module 20 for drying a cleaned substrate. The polishing modules 14a to 14d are arranged along a longitudinal direction of the substrate processing apparatus 1. In a similar way, the first cleaning module 16, the second cleaning module 18, and the drying module 20 are arranged along the longitudinal direction of the substrate processing apparatus 1.

The substrate processing apparatus 1 includes a first transfer robot 22 disposed adjacent to the load port 12, and a transfer module 24 disposed adjacent to the polishing modules 14a to 14d. The first transfer robot 22 receives an unpolished substrate from the load port 12 and passes it to the transfer module 24, and receives a dried substrate from the drying module 20 and returns it to the load port 12. The transfer module 24 transfers the substrate received from the first transfer robot 22 and receives and passes substrates from/to each polishing module 14a to 14d.

The substrate processing apparatus 1 includes a second transfer robot 26 disposed between the first cleaning module 16 and the second cleaning module 18, and a third transfer robot 28 disposed between the second cleaning module 18 and the drying module 20. The second transfer robot 26 receives and passes substrates between the transfer module 24 and each cleaning module 16, 18. The third transfer robot 28 receives and passes substrates from/to each module 18, 20.

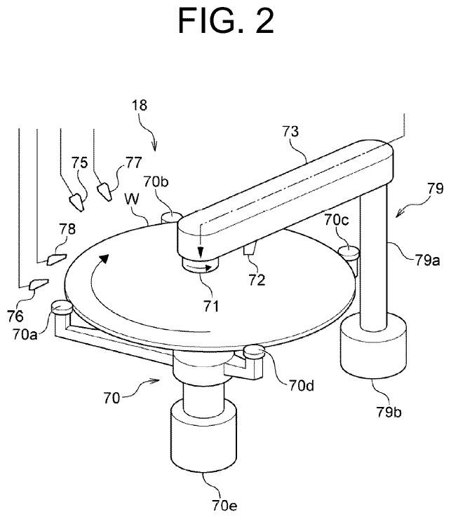

FIG. 2 shows the substrate cleaning apparatus (the second cleaning module 18) in this embodiment. The second cleaning module 18 includes a substrate holding and rotating mechanism 70 which rotates the substrate W while holding it horizontally, a cleaning member 71 which makes contact with the substrate W and scrubs the substrate W, a two-fluid nozzle 72 which sprays two-fluid jet flow toward the substrate W, a cleaning arm 73 connected to the cleaning member 71 and the two-fluid nozzle 72, an oscillation mechanism 79 which oscillates the cleaning arm 73 in the horizontal direction, rinse liquid nozzles 75, 76 which supply rinse liquid for adjusting liquid film thickness toward an upper surface W1 and a lower surface W2 of the substrate W, and pure water nozzles 77, 78 which supply pure water toward the upper surface W1 and the lower surface W2 of the substrate W.

The substrate holding and rotating mechanism 70 includes chucks 70a to 70d which hold the periphery of the substrate W, and a motor 70e connected to the chucks 70a to 70d. When the chucks 70a to 70d holds the substrate W and they are driven by the motor 70e, the substrate W is rotated around its axis.

The cleaning member 71 is a sponge member which has a pencil shape and makes contact with the upper surface W1 of the substrate W and scrubs it while rotating around the central axis of the cleaning member 71. The material for the sponge member preferably has high hydrophilicity and can be PVAc (polyvinyl acetal) and polyurethane, for example. The direction of the central axis of the cleaning member 71 is perpendicular to the substrate W.

The cleaning arm 73 is disposed above the substrate W and is connected to the oscillation mechanism 79. The oscillation mechanism 79 includes a pivot shaft 79a, a rotation mechanism 79b, and a lifting mechanism 79c. One end of the cleaning arm 73 is connected to the pivot shaft 79a, with the cleaning member 71 and the two-fluid nozzle 72 attached to the other end of the cleaning arm 73.

The pivot shaft 79a is connected to the rotation mechanism 79b which pivots the cleaning arm 73, and with the lifting mechanism 79c which moves the pivot shaft 79a up and down. The rotation mechanism 79b is configured to pivot the cleaning arm 73 in a plane parallel to the substrate W by rotating the pivot shaft 79a by a predetermined angle. The lifting mechanism 79c functions to adjust the distance between the two-fluid nozzle 72 and the upper surface W1 of the substrate W. An example of the lifting mechanism 79c can be a motor drive mechanism using a ball screw or an air cylinder.

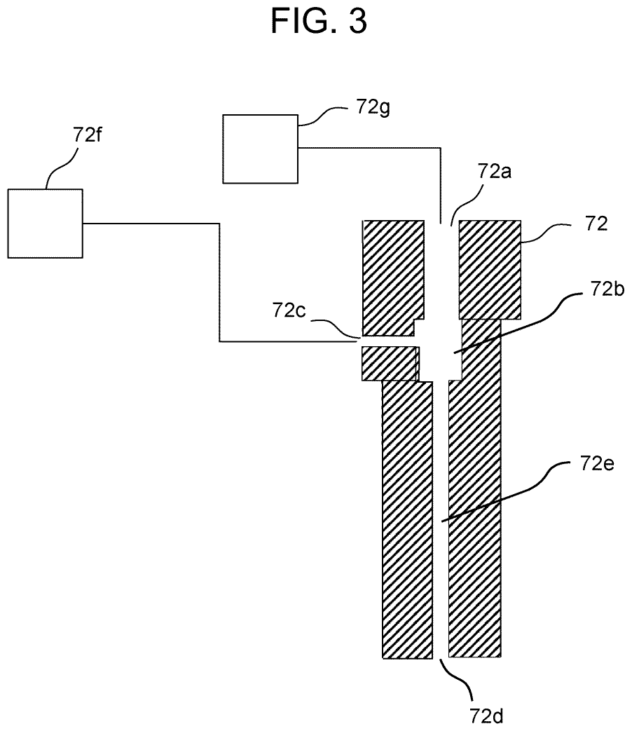

FIG. 3 is a vertical cross-sectional view showing an example of the two-fluid nozzle 72. A gas inlet orifice 72a is formed at an upper end of the two-fluid nozzle 72. Immediately below the gas inlet orifice 72a, a liquid chamber 72b for temporarily storing cleaning liquid and a cleaning liquid inlet orifice 72c in communication with the liquid chamber 72b are formed. A spray orifice 72d is formed at a lower end of the two-fluid nozzle 72, with a flow path 72e formed between the liquid chamber 72b and the spray orifice 72d. Cleaning liquid and gas are supplied to the two-fluid nozzle 72 at the same time. The cleaning liquid fills the liquid chamber 72b, and the gas and the cleaning liquid are mixed in the flow path 72e to form a two-fluid jet flow, which is then sprayed from the spray orifice 72d. The cleaning liquid inlet orifice 72c is coupled to a cleaning liquid source 72f. The cleaning liquid source 72f supplies cleaning liquid for detaching particles adhering to the upper surface W1 of the substrate with two-fluid jet cleaning.

The cleaning liquid preferably has an effect of turning the zeta potentials (the potential at a “slipping plane”, where flowing of liquid starts to occur in an electrical double layer formed in the surroundings) of both particles and the substrate to negative potentials. Specifically, the cleaning liquid can be alkaline cleaning liquid or cleaning liquid that contains an anionic surfactant component. The former in particular can provide high cleaning effect on remaining slurry because it also has the effect of slight etching on silica (silicon dioxide), which is the primary component of abrasive grains. The cleaning liquid may also contain water-soluble organic solvent as a component. The cleaning liquid is regulated at a temperature equal to or higher than room temperature and lower than the boiling point of pure water.

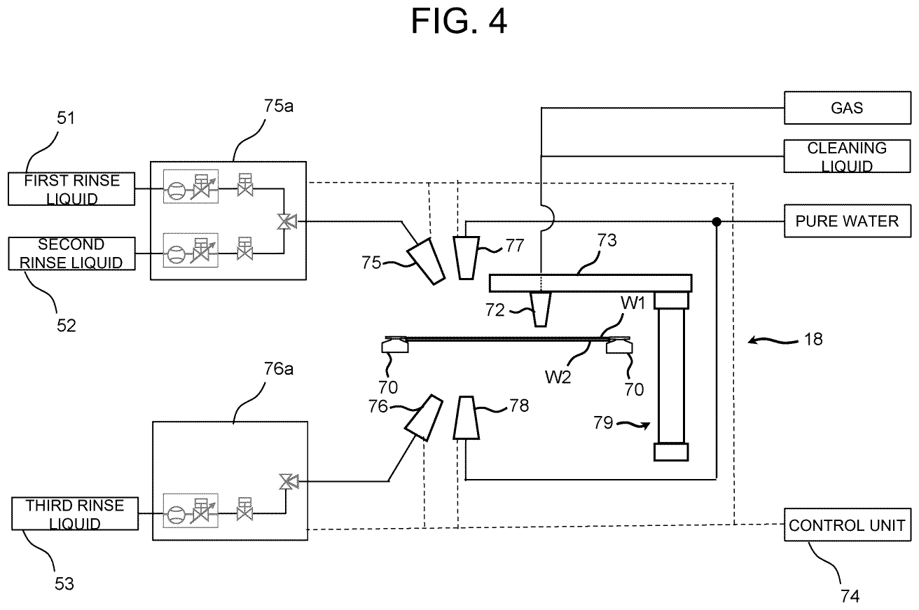

FIG. 4 is a schematic diagram illustrating a configuration of the substrate cleaning apparatus (the second cleaning module 18) in this embodiment. As shown in FIG. 4, the rinse liquid nozzle 75 is connected to the first rinse liquid source 51 and the second rinse liquid source 52, and the rinse liquid nozzle 76 is connected to the third rinse liquid source 53. The rinse liquid nozzle 75 supplies first rinse liquid or second rinse liquid to the upper surface W1 of the substrate, and the rinse liquid nozzle 76 supplies third rinse liquid to the lower surface W2 of the substrate.

An automatic switching valve 75a is provided between the rinse liquid nozzle 75, and the first rinse liquid source 51 and the second rinse liquid source 52, while an automatic switching valve 76a is provided between the rinse liquid nozzle 76 and the third rinse liquid source 53. The timing of supply of the first rinse liquid and the timing of supply of the second rinse liquid are switchable according to an automated operation recipe. The timing of supply of the third rinse liquid is the same as the timing of supply of the second rinse liquid.

The first rinse liquid source 51 supplies the rinse liquid nozzle 75 with the first rinse liquid for forming a liquid film that is thinner than the liquid film formed by dispensing of pure water at room temperature on the upper surface W1 of the substrate. The first rinse liquid is preferably liquid that has smaller surface tension than pure water at room temperature and is soluble in water. Specifically, examples include liquid that contains an organic solvent such as alcohol like isopropyl alcohol (IPA) and dimethyl sulfoxide (DMSO), as a component. The latter in particular can provide higher cleaning effect when used in conjunction with cleaning liquid for two-fluid jet cleaning because it also has the effect of dissolving organic matter, which are difficult to remove with aqueous cleaning liquid. The first rinse liquid is preferably regulated at a temperature higher than room temperature and lower than the boiling point of pure water.

In this embodiment, liquid that gas smaller surface tension than pure water at room temperature can be used as the first rinse liquid, such as shown below, for example. Shown below are the values of surface tension under room temperature conditions.
isopropyl alcohol (IPA) surface tension: 0.021 N/m
dimethyl sulfoxide (DMSO) surface tension: 0.044 N/m
ethanol surface tension: 0.022 N/m
methyl ethyl ketone (MEK) surface tension: 0.025 N/m
hydrofluoroether (HFE) surface tension: 0.014 N/m

The second rinse liquid source 52 supplies the rinse liquid nozzle 75 with the second rinse liquid for discharging particles that have been detached from the upper surface W1 of the substrate with the cleaning liquid sprayed from the two-fluid nozzle outside of the system. The second rinse liquid recovers the liquid film on the upper surface W1 of the substrate, which has been temporally thinned due to the first rinse liquid supply process and the two-fluid jet cleaning process in the preceding step, thereby suppressing re-adhesion of detached particles to the upper surface W1 of the substrate.

For the second rinse liquid, cleaning liquid with the same components as that used in the two-fluid jet cleaning process may be used. When the second rinse liquid contains the same components as the cleaning liquid, the effect of suppressing re-adhesion of particles is further improved by the effect of making the zeta potential a negative potential. For the second rinse liquid, liquid that contains the organic solvent as a component of the foregoing first rinse liquid may be used. When the second rinse liquid contains the organic solvent component of the first rinse liquid, the effect of removing organic matter is further improved. The second rinse liquid is preferably regulated at a temperature higher than room temperature and lower than the boiling point of pure water.

The third rinse liquid source 53 supplies the rinse liquid nozzle 76 with the third rinse liquid for discharging those particles that have moved down to the lower surface W2 of the substrate outside of the system. The third rinse liquid can be the same liquid as the second rinse liquid. The third rinse liquid is also preferably regulated at a temperature higher than room temperature and lower than the boiling point of pure water. In this embodiment, liquid that contains at least one or more of ammonia, quaternary ammonium compound, amino alcohols, and amine compound, for example, can be used for the second rinse liquid and/or the third rinse liquid.

The control unit 74 performs various kinds of control for cleaning the surfaces of the substrate W. Specifically, the control unit 74 performs substrate cleaning control, which includes starting supply of the first rinse liquid to the surface of the substrate W from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid. The substrate cleaning control will be discussed later with reference to the drawings.

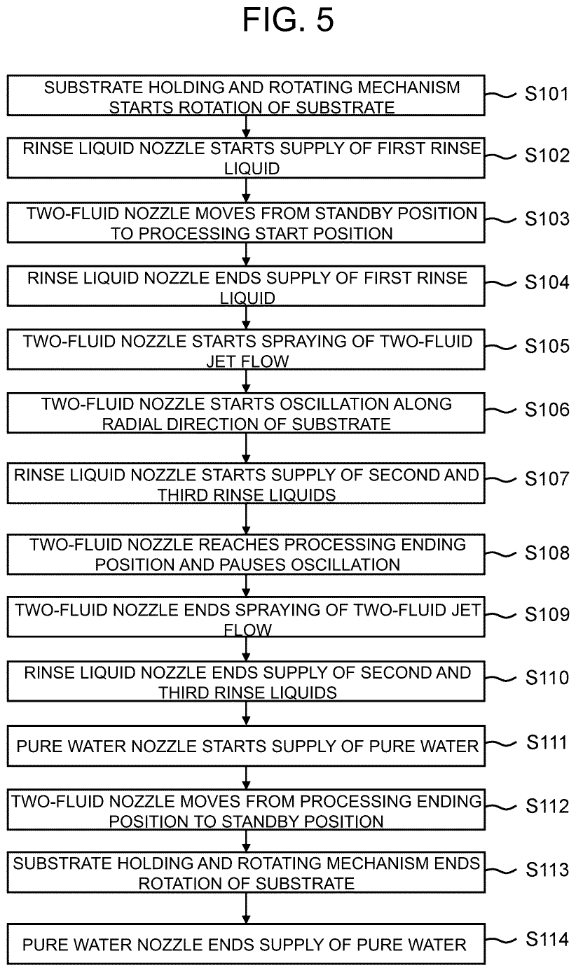

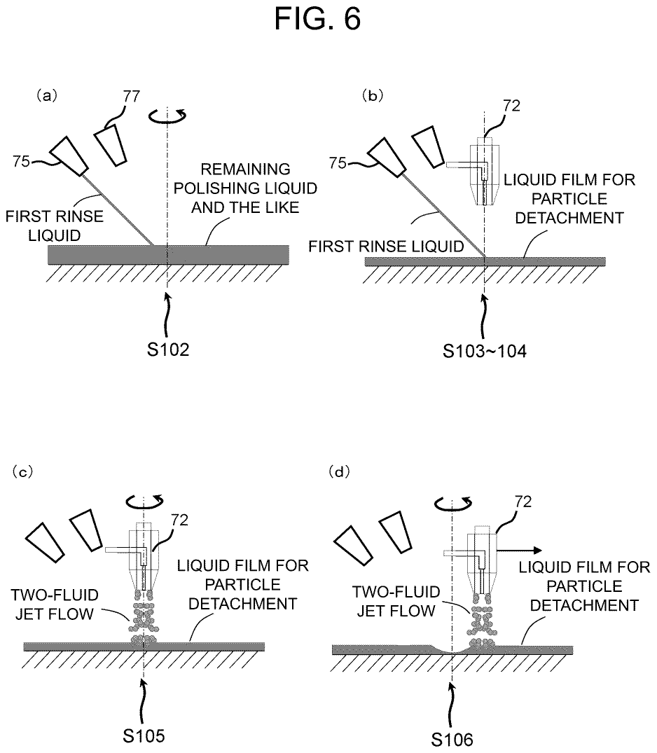

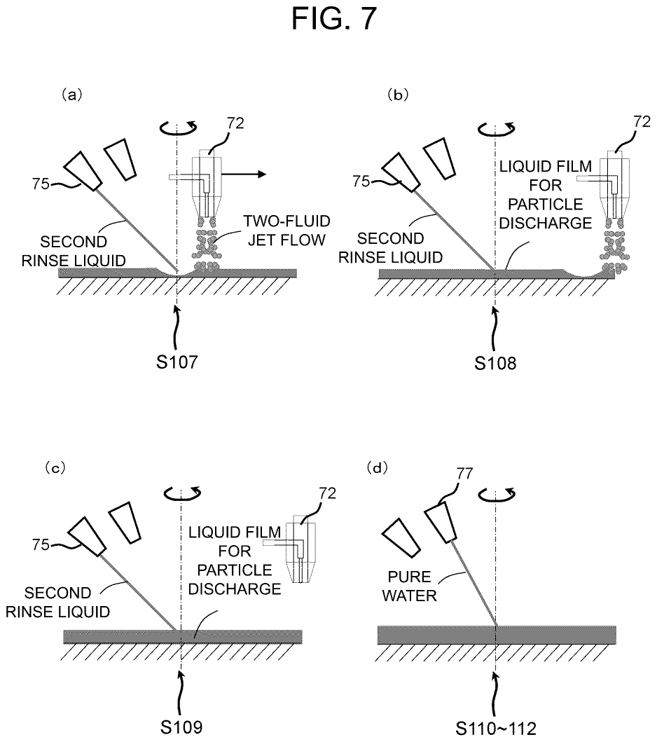

For the substrate cleaning apparatus configured as described above, its operation (substrate cleaning control) is now described with reference to FIGS. 5 to 7.

As shown in FIG. 5, in order to clean the surfaces of a substrate with the substrate cleaning apparatus in this embodiment, a substrate W on which the cleaning process at the first cleaning module 16 has been done is first transferred to the second cleaning module 18 (see FIG. 1). The substrate holding and rotating mechanism 70 holds the substrate W transferred to the second cleaning module 18 and starts rotation of the substrate W in this condition (see step S101).

Next, the automatic switching valve 75a is changed to a first rinse liquid supply setting, and supply of the first rinse liquid from the rinse liquid nozzle 75 is started to the upper surface W1 of the substrate (see step S102). Next, with pivoting of the cleaning arm 73, the two-fluid nozzle 72 moves from a standby position to a processing start position located above the center of the upper surface W1 of the substrate (see step S103). Next, the automatic switching valve 75a is changed to supply stop setting and supply of the first rinse liquid is stopped (see step S104).

Subsequently, the two-fluid nozzle 72 starts spraying of a mixed jet flow of gas and cleaning liquid (see step S105). Next, with pivoting of the cleaning arm 73, the two-fluid nozzle 72 starts a motion of radially moving from the processing start position located above the center of the upper surface W1 of the substrate toward a processing ending position located above the edge of the upper surface W1 of the substrate (see step S106). Next, the automatic switching valves 75a, 76a are changed to the second rinse liquid supply setting, and supply of the second rinse liquid and the third rinse liquid from the rinse liquid nozzles 75, 76 to the upper surface W1 and the lower surface W2 of the substrate is started (see step S107).

At this point, the second rinse liquid will be supplied to a portion of the upper surface W1 of the substrate where the liquid film has been temporarily thinned immediately after the passage of the two-fluid nozzle 72. That is, particles detached from the upper surface W1 of the substrate in the two-fluid jet cleaning process are quickly diffused by the liquid flow formed by the second rinse liquid and efficiently discharged outside of the system. The series of processes at steps S104 through S107 may be either sequential processes or concurrent processes.

Once the two-fluid nozzle 72 has reached the above-mentioned processing ending position, the motion of the cleaning arm 73 is paused (see step S108). Next, the two-fluid nozzle 72 ends the spraying of the mixed jet flow of gas and cleaning liquid (see step S109). Next, the automatic switching valves 75a, 76a are changed to supply pausing setting and supply of the second rinse liquid and the third rinse liquid is finished (see step S110).

Next, the pure water nozzles 77, 78 start supply of pure water to the upper surface W1 and the lower surface W2 of the substrate (see step S111). Next, the two-fluid nozzle 72 moves from the processing ending position to the standby position (see step S112). The series of processes at steps S109 through S112 may be either sequential processes or concurrent processes. In addition, as particles tend to remain near the edges of the substrate, variations may be implemented in order to address this, such as intentionally increasing the amount of time from step S108 to step S109 or repeating all or some of steps S102 to S110.

When the process at step S111 has continued for a certain amount of time, the substrate holding and rotating mechanism 70 finishes rotation of the substrate W (see step S113). Next, the pure water nozzles 77, 78 finish supply of pure water to the upper surface W1 and the lower surface W2 of the substrate (see step S114). Upon completion of the cleaning process in the series of steps, holding of the substrate W by the substrate holding and rotating mechanism 70 is released and also the substrate W is transferred to the drying module 20 by the third transfer robot 28 (see FIG. 1).

With such a substrate cleaning apparatus (the second cleaning module 18), the first rinse liquid is dispensed to the surface W1 of the substrate W in a stage earlier than the cleaning process with the two-fluid nozzle 72. Hence, a liquid film thinner than the liquid film formed by the dispensing of pure water at room temperature is formed on the surface W1 of the substrate W. Thus, a cleaning process with the two-fluid nozzle 72 is performed with no particles clinging to the surface W1 of the substrate W.

With the substrate cleaning apparatus (the second cleaning module 18), in the stage of the cleaning process with the two-fluid nozzle 72, liquid present near particle surfaces is replaced by cleaning liquid containing an alkaline component or a surfactant component sprayed from the two-fluid nozzle 72 in a short time. Thus, not only the physical action of a liquid flow but also the chemical action of the cleaning liquid components mentioned above contribute to detachment of particles from the substrate.

With the substrate cleaning apparatus (the second cleaning module 18), in the stage of the cleaning process with the two-fluid nozzle 72, the action of the two-fluid nozzle 72 spraying cleaning liquid while moving over the substrate W via the oscillation mechanism 79 and the action of dispensing the second rinse liquid to the surface W1 of the substrate W are performed simultaneously. Thus, detached particles are diffused by the liquid flow of the second rinse liquid to be discharged outside of the system, and are inhibited from re-adhering to the surface W1 of the substrate W. In this manner, two-fluid jet cleaning with sufficient cleaning performance even for particles of a size of 100 nm or smaller is provided.

In particular, in this embodiment, the first rinse liquid is first supplied from the rinse liquid nozzle 75 to the surface W1 of the substrate W. After formation of a liquid film for particle detachment on the surface W1 of the substrate W with the first rinse liquid, spraying of two-fluid jet flow to the surface W1 of the substrate W is started from the two-fluid nozzle 72 and oscillation of the cleaning arm 73 is started. By doing so, a cleaning process with the cleaning liquid is performed with no particles clinging to the surface of the substrate W, providing high cleaning effect. For example, sufficient cleaning effect is obtained even for particles with a size of 100 nm or smaller.

Furthermore, in this embodiment, after movement of the cleaning arm 73 is started, the second rinse liquid is supplied to the surface W1 of the substrate W from the rinse liquid nozzle 75 and a liquid film for particle discharge is formed on the surface of the substrate with the second rinse liquid. As a result, detached particles are diffused by a liquid flow to be discharged outside of the system, and inhibited from re-adhering to the surface of the substrate, providing high cleaning effect.

Additionally, since this embodiment uses liquid with smaller surface tension than pure water as the first rinse liquid, the thickness of liquid film for particle detachment formed on the surface W1 of the substrate W with the first rinse liquid can be easily controlled to be thin. When liquid film is not present on the surface of the substrate, particles cling to the surface of the substrate and become difficult to detach. On the other hand, when the liquid film on the surface of the substrate is too thick, cleaning liquid is less likely to reach the surface of the substrate, lowering the cleaning effect. This embodiment can provide high cleaning effect because liquid film (thin liquid film) for particle detachment can be formed on the surface W1 of the substrate W. Where the first rinse liquid contains an organic solvent component, the effect of removing organic matter from the surface of the substrate is provided by the first rinse liquid.

Since this embodiment uses liquid that contains either an alkaline component or a surfactant component as the cleaning liquid, particles on the surface of the substrate can be detached not only by physical action of a liquid flow but also by chemical action (e.g., the effect of making the zeta potential assume a negative charge), providing high cleaning effect.

In this embodiment, when the same liquid as the cleaning liquid is used for the second rinse liquid, the effect of suppressing re-adhesion of particles with chemical action (e.g., the effect of making the zeta potential assume a negative charge) is obtained. Alternatively, when the same liquid as the first rinse liquid is used for the second rinse liquid, the effect of removing organic matter from the surface of the substrate can be provided if the first rinse liquid is an organic solvent.

While embodiments of the present invention have been described by way of illustration, the scope of the present invention is not limited to them and modifications and variations can be made as needed for a purpose within the scope as set forth in claims.

For example, the cleaning arm movement mechanism in the foregoing embodiment was described as being an oscillation mechanism 79 that oscillates the cleaning arm from the center of the substrate in the radial direction of the substrate; however, the scope of the present invention is not limited thereto. The cleaning arm movement mechanism may also be a translation mechanism that translates the cleaning arm in the radial direction of the substrate.

Also, the jet flow nozzle in the foregoing embodiment was described as being a two-fluid nozzle 72; however, the scope of the present invention is not limited thereto. The jet flow nozzle may also be a one-fluid nozzle that sprays a jet flow (jet) of liquid alone.

As has been described above, the substrate cleaning apparatus according to the present invention has the effect of providing high cleaning effect, and can be advantageously applied to a production process of a semiconductor device, a production process of a flat panel display, a production process of an image sensor such as CMOS and CCD, and a production process of magnetic film on MRAM, for example.

### REFERENCE SIGNS LIST

1 substrate processing apparatus
2 polishing section
4 cleaning section
10 housing
12 load port
14a-d polishing module
16 first cleaning module
18 second cleaning module (substrate cleaning apparatus)
20 drying module
22 first transfer robot
24 transfer module
26 second transfer robot
28 third transfer robot
70 substrate holding and rotating mechanism
72 two-fluid nozzle
73 cleaning arm
74 control unit
75 rinse liquid nozzle
76 rinse liquid nozzle
77 pure water nozzle
78 pure water nozzle
79 oscillation mechanism
W substrate
W1 upper surface
W2 lower surface

1. A substrate cleaning apparatus comprising:
a substrate holding and rotating mechanism which holds a substrate and rotates the substrate at a predefined rotation number;
a cleaning arm disposed above the substrate;
a cleaning arm movement mechanism which moves the cleaning arm over the substrate in a predefined direction of movement;
a jet flow nozzle which is provided on the cleaning arm and dispenses a jet flow of cleaning liquid to a surface of the substrate;
a rinse liquid nozzle which is disposed above the substrate and dispenses a first rinse liquid supplied from a first rinse liquid source or a second rinse liquid supplied from a second rinse liquid source to the surface of the substrate; and
a control unit, wherein the control unit performs substrate cleaning control comprising: starting supply of the first rinse liquid to the surface of the substrate from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid.

2. The substrate cleaning apparatus according to claim 1, wherein the first rinse liquid is liquid with smaller surface tension than that of pure water.

3. The substrate cleaning apparatus according to claim 2, wherein the first rinse liquid is liquid containing an organic solvent component.

4. The substrate cleaning apparatus according to claim 1, wherein the cleaning liquid is liquid containing at least one component of an alkaline component or a surfactant component.

5. The substrate cleaning apparatus according to claim 2, wherein the second rinse liquid is the same liquid as the cleaning liquid or the first rinse liquid.

6. The substrate cleaning apparatus according to claim 4, wherein the second rinse liquid is the same liquid as the cleaning liquid or the first rinse liquid.

7. The substrate cleaning apparatus according to claim 1, wherein the jet flow nozzle is a two-fluid nozzle that sprays a two-fluid jet flow of the cleaning liquid and gas to the surface of the substrate.

8. A substrate cleaning method that is performed in a substrate cleaning apparatus,
the substrate cleaning apparatus comprising:
a substrate holding and rotating mechanism which holds a substrate and rotates the substrate at a predefined rotation number;
a cleaning arm disposed above the substrate;
a cleaning arm movement mechanism which moves the cleaning arm over the substrate in a predefined direction of movement;
a jet flow nozzle which is provided on the cleaning arm and dispenses a jet flow of cleaning liquid to a surface of the substrate; and
a rinse liquid nozzle which is disposed above the substrate and dispenses a first rinse liquid supplied from a first rinse liquid source or a second rinse liquid supplied from a second rinse liquid source to the surface of the substrate;
the substrate cleaning method comprising:
starting supply of the first rinse liquid to the surface of the substrate from the rinse liquid nozzle; after formation of a liquid film for particle detachment on the surface of the substrate with the first rinse liquid, starting dispensing of a jet flow of the cleaning liquid to the surface of the substrate from the jet flow nozzle and starting movement of the cleaning arm; and after the movement of the cleaning arm is started, starting supply of the second rinse liquid to the surface of the substrate from the rinse liquid nozzle, and forming a liquid film for particle discharge on the surface of the substrate with the second rinse liquid.
